(19) United States
(12) Patent Application Publication
(10) Pub. No.: US 2026/0182420 A1
(43) Pub. Date: Jun. 25, 2026

(54) Electronic Apparatus

(71) Applicant: SEIKO EPSON CORPORATION, Tokyo (JP)

(72) Inventors: Satoru IMAI, Minamimaki (JP); Yosuke OGURA, Shiojiri (JP); Yasushige HORI, Asahi (JP)

(21) Appl. No.: 19/431,148

(22) Filed: Dec. 23, 2025

(30) Foreign Application Priority Data
Dec. 25, 2024 (JP) 2024-229399

(51) Int. Cl. H10W 70/65

(52) U.S. Cl. CPC H10W 70/65

(57) ABSTRACT

An electronic apparatus includes a printed circuit board, in which in the printed circuit board, in a first direction, no pad is arranged between a fifth pad and a sixth pad and a first side, and a first pad, a third pad, and the fifth pad at least partially overlap each other, in a second direction, the fifth pad and the sixth pad are adjacent to each other, the third pad and a fourth pad are adjacent to each other, the first pad and a second pad are adjacent to each other, a shortest distance between the third pad and the fourth pad is longer than a shortest distance between the first pad and the second pad, and a shortest distance between the fifth pad and the sixth pad is longer than the shortest distance between the third pad and the fourth pad.

The present application is based on, and claims priority from JP Application Serial Number 2024-229399, filed December 25, 2024, the disclosure of which is hereby incorporated by reference herein in its entirety.

### BACKGROUND

### 1. Technical Field

The present disclosure relates to an electronic apparatus.

### 2. Related Art

As the high integration and high functionality of a semiconductor device progress, many functions tend to be incorporated into a single semiconductor device. Therefore, as the number of terminals of the semiconductor device increases, it is necessary to arrange a large number of terminals at a narrow pitch. However, when a large number of terminals are arranged at a narrow pitch, various problems occur, for example, a malfunction occurs due to the influence of electrical crosstalk between the terminals or the like, and an increase in a mounting area when a large number of terminals are arranged without the malfunction.

In order to address such problems, for example, as disclosed in JP-A-2006-100710 and JP-A-2003-188508, in a substrate on which a semiconductor device is mounted, a technique is known in which a pad coupled to a terminal electrode on the outermost periphery of the semiconductor device is formed in an oval shape or is made relatively small so that wiring is led out from the pad located inside the outermost periphery.

However, when the high integration of the semiconductor device further progresses, a large number of terminals of the semiconductor device are arranged at a narrower pitch, and thus the pitch of the pads on the substrate is also narrowed. However, a configuration in which the wiring is led out through the space between the pads arranged at a narrower pitch has not been sufficiently studied, and there is room for improvement.

### SUMMARY

According to one aspect of the present disclosure, an electronic apparatus includes a printed circuit board, and a semiconductor device mounted on the printed circuit board, in which the semiconductor device includes an integrated circuit chip, and an integrated circuit substrate on which the integrated circuit chip is mounted, the integrated circuit substrate is provided with a plurality of terminals, the printed circuit board is provided with a plurality of pads, each of the plurality of terminals is coupled to each of the plurality of pads, the plurality of terminals include a first terminal, a second terminal, a third terminal, a fourth terminal, a fifth terminal, and a sixth terminal, the plurality of pads include a first pad, a second pad, a third pad, a fourth pad, a fifth pad, and a sixth pad, the first terminal is coupled to the first pad, the second terminal is coupled to the second pad, the third terminal is coupled to the third pad, the fourth terminal is coupled to the fourth pad, the fifth terminal is coupled to the fifth pad, the sixth terminal is coupled to the sixth pad, the integrated circuit substrate has a first side, a second side facing the first side, a third side, and a fourth side facing the third side, the fifth pad and the sixth pad are arranged along the first side, in a first direction from the second side toward the first side, none of the plurality of pads is arranged between the fifth pad and the first side, in the first direction, none of the plurality of pads is arranged between the sixth pad and the first side, in the first direction, the first pad, the third pad, and the fifth pad at least partially overlap, in a second direction from the third side toward the fourth side, the fifth pad and the sixth pad are adjacent to each other, in the second direction, the third pad and the fourth pad are adjacent to each other, in the second direction, the first pad and the second pad are adjacent to each other, a shortest distance between the third pad and the fourth pad is longer than a shortest distance between the first pad and the second pad, and a shortest distance between the fifth pad and the sixth pad is longer than the shortest distance between the third pad and the fourth pad.

### BRIEF DESCRIPTION OF THE DRAWINGS

FIG. 1 is an external perspective view of an electronic apparatus.

FIG. 2 is a diagram showing an example of a functional configuration of the electronic apparatus.

FIG. 3 is a sectional view showing a structure of a semiconductor device.

FIG. 4 is a perspective view of a terminal mounting surface of a package.

FIG. 5 is a functional block diagram of an integrated circuit chip.

FIG. 6 is a plan view of a portion of a printed circuit board.

FIG. 7 is a plan view of a portion of the printed circuit board.

FIG. 8 is a plan view of a portion of the printed circuit board.

### DESCRIPTION OF EMBODIMENTS

Hereinafter, preferred embodiments of the present disclosure will be described with reference to the drawings. The drawings to be used are for convenience of description. The embodiments to be described below do not unduly limit the contents of the present disclosure described in the scope of claims. Furthermore, not all of the configurations described below are essential constituent elements of the present disclosure.

Hereinafter, a multifunction peripheral having a printing function and a scanning function will be described as an example of an electronic apparatus according to the present disclosure, and the electronic apparatus of the present embodiment will be described.

### 1. Structure of Electronic Apparatus

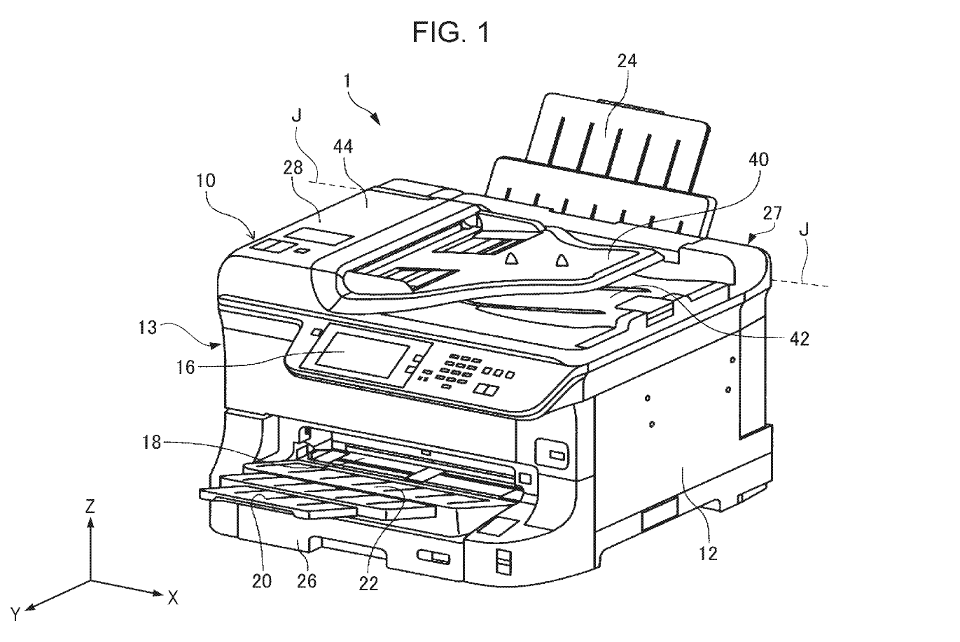

FIG. 1 is an external perspective view of an electronic apparatus 1. In the following, description is given using an X direction, a Y direction, and a Z direction that are orthogonal to each other. In addition, a starting point side of an arrow indicating the X direction may be referred to as a -X side and a tip side thereof may be referred to as a +X side, a starting point side of an arrow indicating the Y direction may be referred to as a -Y side and a tip side thereof may be referred to as a +Y side, and a starting point side of an arrow indicating the Z direction may be referred to as a -Z side and a tip side thereof may be referred to as a +Z side.

The electronic apparatus 1 includes an apparatus main body 12 having a substantially rectangular parallelepiped shape as a whole. The apparatus main body 12 includes a recording device 13 that performs recording on a sheet and an image reading device 10 that is provided on the recording device 13 and that generates an image by reading information such as a picture, a character, or a photograph formed on a mounted document. For example, the image generated by the image reading device 10 is printed on a sheet by the recording device 13.

The image reading device 10 includes an auto document feeder (ADF) 27 which is an automatic document feeder. The ADF 27 is provided rotatably on a rear surface side of the apparatus main body 12, which is the -Y side, serving as a fulcrum of rotation axis J, and also has a function as a top plate that can be opened and closed with respect to an upper portion of the apparatus main body 12.

The ADF 27 includes a document transport section 28 including a drive mechanism for transporting a document, a document mounting surface 40, and a document discharging surface 42. The document mounted on the document mounting surface 40 is fed to the inside of the image reading device 10 by the document transport section 28, is read, and then is discharged to be mounted on the document discharging surface 42.

An operation section 16 is provided in an upper portion on a front surface side, which is the +Y side of the apparatus main body 12, and the operation section 16 is configured to include a power button, a print setting button, a display panel, and the like for operating the electronic apparatus 1.

A rear surface side tray 24 on which sheets are mounted is provided on the rear surface side which is the -Y side of the apparatus main body 12. The sheets mounted on the rear surface side tray 24 are fed to the recording device 13 and recorded.

On a bottom surface side which is the -Z side of a front surface side tray 22, a sheet accommodating section 26 in which a plurality of sheets are accommodated is provided. The sheet accommodating section 26 is provided in a lower portion of the apparatus main body 12 so as to be slidable in the Y direction, and is configured to be attachable to and detachable from the apparatus main body 12. The sheet mounted on the sheet accommodating section 26 is fed to the recording device 13 and recorded.

On the front surface side of the apparatus main body 12, a drawer section 20 which is attached to the front surface side tray 22 and is slidable in the Y direction is provided. The sheet fed from the rear surface side tray 24 or the sheet accommodating section 26 to the recording device 13 and recorded is discharged from an opening section 18 provided on the front surface side of the apparatus main body 12 and is mounted on the front surface side tray 22 or the drawer section 20 in a state of being drawn out from the front surface side tray 22.

### 2. Functional Configuration of Electronic Apparatus

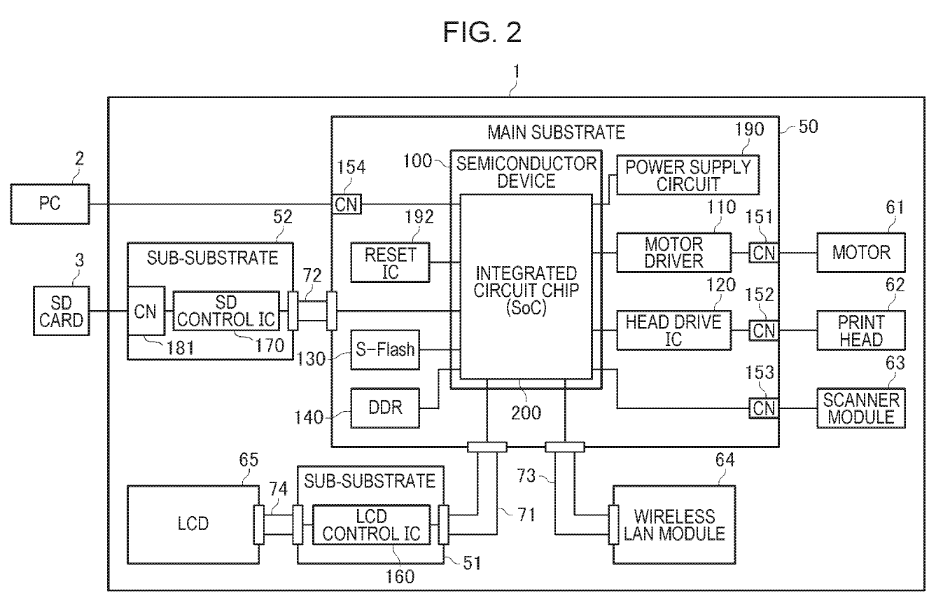

FIG. 2 is a diagram showing an example of a functional configuration of the electronic apparatus 1. As shown in FIG. 2, the electronic apparatus 1 includes a main substrate 50, a sub-substrate 51, and a sub-substrate 52. The main substrate 50 and the sub-substrates 51 and 52 are, for example, printed circuit boards having a multilayer structure.

On the main substrate 50, a semiconductor device 100 having an integrated circuit chip 200, a motor driver 110, a head drive IC 120, a serial flash memory 130, a DDR 140, a power supply circuit 190, and a reset IC 192 are mounted. DDR is an abbreviation for Double-Data-Rate SDRAM. The main substrate 50 is provided with connectors 151, 152, 153, and 154.

An LCD control IC 160 is mounted on the sub-substrate 51. The sub-substrate 51 is coupled to the main substrate 50 by a cable 71.

On the sub-substrate 52, an SD control IC 170 is mounted, and a connector 181 is provided. The sub-substrate 52 is coupled to the main substrate 50 by a cable 72.

In addition, the electronic apparatus 1 includes various motors 61, a print head 62, a scanner module 63, a wireless LAN module 64, and an LCD 65. LAN is an abbreviation for Local Area Network. LCD is an abbreviation for Liquid Crystal Display.

The motor 61 is coupled to the main substrate 50 via the connector 151, and is driven by the motor driver 110.

The print head 62 is provided in the recording device 13, is coupled to the main substrate 50 via the connector 152, and is driven by the head drive IC 120.

The scanner module 63 is provided in the image reading device 10, is coupled to the main substrate 50 via the connector 153, and is controlled by the integrated circuit chip 200. Further, the scanner module 63 transmits scan data generated by scanning a document to the integrated circuit chip 200.

The wireless LAN module 64 is a module that performs wireless data communication with an external device of the electronic apparatus 1. The wireless LAN module 64 is coupled to the main substrate 50 via a cable 73, and is controlled by the integrated circuit chip 200. Further, the wireless LAN module 64 performs USB communication with the integrated circuit chip 200.

The LCD 65 is included in the operation section 16 and is a display panel that displays various kinds of information. The LCD 65 is coupled to the sub-substrate 51 via a cable 74 and is controlled by the LCD control IC 160.

The LCD control IC 160 is coupled to the LCD 65 via the cable 74 and is a circuit that controls display of various kinds of information on the LCD 65. The LCD control IC 160 is controlled by the integrated circuit chip 200.

The SD control IC 170 is a circuit that controls writing data to and reading data from an SD card 3 inserted into the connector 181. The SD control IC 170 is controlled by the integrated circuit chip 200. Further, the SD control IC 170 performs USB communication with the integrated circuit chip 200.

The motor driver 110 is coupled to the motor 61 via the connector 151 and is a circuit that drives the motor 61. The motor driver 110 is controlled by the integrated circuit chip 200.

The head drive IC 120 is coupled to the print head 62 via the connector 152 and is a circuit that drives the print head 62. The head drive IC 120 is controlled by the integrated circuit chip 200.

The serial flash memory 130 and the DDR 140 are storage devices that store various kinds of data, respectively, and writing and reading of data are controlled by the integrated circuit chip 200.

The power supply circuit 190 supplies power to the semiconductor device 100, the motor driver 110, the head drive IC 120, the serial flash memory 130, and the DDR 140. For example, the power supply circuit 190 generates a power supply voltage of several volts and supplies the power supply voltage to the semiconductor device 100, the motor driver 110, the head drive IC 120, the serial flash memory 130, and the DDR 140. In addition, the power supply circuit 190 generates a power supply voltage of several tens of volts for driving the motor 61 and the print head 62, and supplies the power supply voltage to the motor driver 110 and the head drive IC 120. The motor 61 and the print head 62 are operated with power supplied from the power supply circuit 190 via the motor driver 110 and the head drive IC 120, respectively. The power supply circuit 190 is controlled by the integrated circuit chip 200.

The reset IC 192 monitors a power supply voltage or the like of the semiconductor device 100, and resets the semiconductor device 100 when it is determined to be abnormal. The reset IC 192 is controlled by the integrated circuit chip 200.

As described above, the integrated circuit chip 200 is an SoC that controls the motor driver 110, the head drive IC 120, the serial flash memory 130, the DDR 140, the scanner module 63, the wireless LAN module 64, the LCD control IC 160, the SD control IC 170, the power supply circuit 190, and the reset IC 192. SoC is an abbreviation for System On Chip.

The integrated circuit chip 200 is coupled to a PC2 outside the electronic apparatus 1 via the connector 154, and performs data communication with the PC2. The connector 154 is, for example, a USB connector.

### 3. Structure of Semiconductor Device

The semiconductor device 100 has a surface-mount package form represented by, for example, a System in Package (SiP), a Ball Grid Array (BGA), a Land Grid Array (LGA), a Wafer Process Package (WPP), or the like. Hereinafter, the structure of the semiconductor device 100 will be described by exemplifying a case where the package form of the semiconductor device 100 is a BGA.

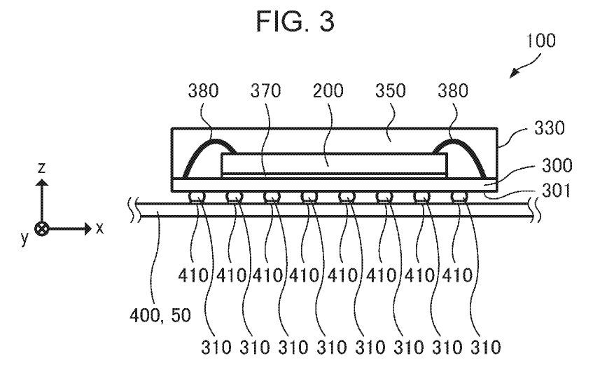

FIG. 3 is a sectional view showing a structure of the semiconductor device 100. In the following, description is given using an x direction, a y direction, and a z direction that are independent of the X direction, the Y direction, and the Z direction shown in FIG. 1, and are orthogonal to each other. In addition, a starting point side of an arrow indicating the x direction may be referred to as a -x side and a tip side thereof may be referred to as a +x side, a starting point side of an arrow indicating the y direction may be referred to as a -y side and a tip side thereof may be referred to as a +y side, and a starting point side of an arrow indicating the z direction may be referred to as a -z side and a tip side thereof may be referred to as a +z side.

As shown in FIG. 3, the semiconductor device 100 includes a base substrate 300, the integrated circuit chip 200, and a housing 350.

The housing 350 is located on the +z side of the integrated circuit chip 200 and is bonded to the base substrate 300 so as to cover the integrated circuit chip 200. The housing 350 contains an epoxy resin or the like and protects the integrated circuit chip 200.

The base substrate 300 is located on the -z side of the integrated circuit chip 200. The integrated circuit chip 200 is mounted on the base substrate 300 by a bonding member 370 such as an adhesive. The base substrate 300 and the integrated circuit chip 200 are electrically coupled to each other via bonding wires 380.

The base substrate 300 is provided with a plurality of wiring patterns and a plurality of electrodes (not shown). The bonding wire 380 is electrically coupled to an electrode (not shown) formed on a surface of the base substrate 300 on the +z side. Further, a plurality of electrodes (not shown) are provided on a surface of the base substrate 300 on the -z side. A solder ball 310 is attached to each of the plurality of electrodes provided on the surface of the base substrate 300 on the -z side. That is, the base substrate 300 is provided with a plurality of solder balls 310 which are a plurality of terminals. A plurality of pads 410 and a plurality of wirings (not shown) are provided on a printed circuit board 400, which is the main substrate 50 of FIG. 2, and each of the plurality of solder balls 310 and each of the plurality of pads 410 are coupled. The base substrate 300 is electrically coupled to the printed circuit board 400 by the plurality of solder balls 310. The plurality of solder balls 310 constitute a so-called ball grid array that electrically and mechanically couples the base substrate 300 and the printed circuit board 400. In the following description, the surface of the base substrate 300 on the -z side to which the plurality of solder balls 310 are attached is referred to as a terminal mounting surface 301.

The package 330 is constituted by the ball grid array including the base substrate 300, the housing 350, and the plurality of solder balls 310. The integrated circuit chip 200 is mounted on the base substrate 300 which is an internal substrate of the package 330.

In the semiconductor device 100 configured as described above, a signal input to the semiconductor device 100 via the plurality of solder balls 310 provided on the terminal mounting surface 301 propagates via the electrodes and the wiring pattern provided on the base substrate 300 and the bonding wires 380, and is input to the integrated circuit chip 200. In addition, the signal output from the integrated circuit chip 200 is input to the plurality of pads 410 of the printed circuit board 400 via the bonding wires 380, the electrode and wiring pattern provided on the base substrate 300, and the plurality of solder balls 310.

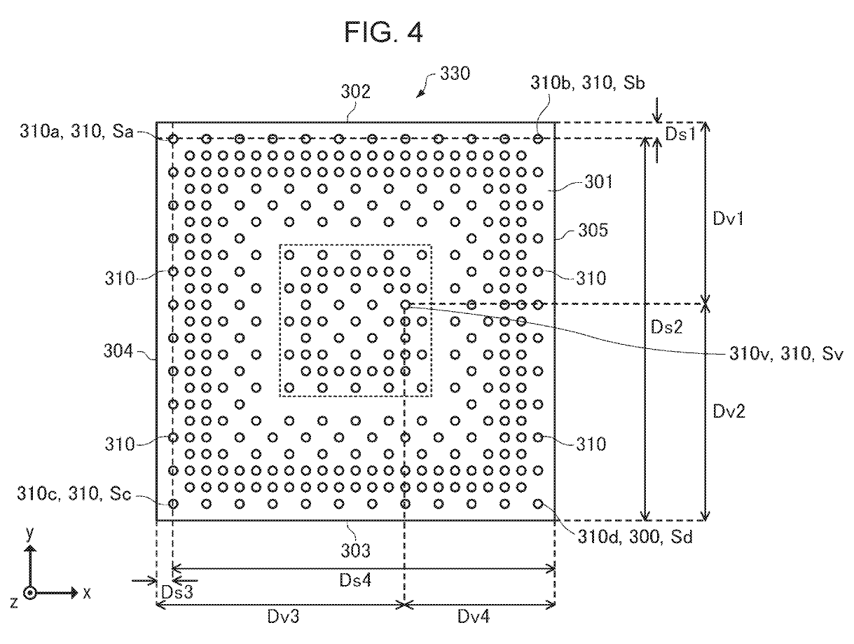

FIG. 4 is a perspective view of the terminal mounting surface 301 of the base substrate 300 of the package 330 as viewed from the +z side. As shown in FIG. 4, the base substrate 300 of the package 330 has a side 302 extending in the x direction, a side 303 extending in the x direction and facing the side 302, a side 304 extending in the y direction, and a side 305 extending in the y direction and facing the side 304. Each of the sides 304 and 305 intersects with the sides 302 and 303. That is, the base substrate 300 has a substantially rectangular shape with the sides 302, 303, 304, and 305 as an outer periphery.

As shown in FIG. 4, on the terminal mounting surface 301 of the base substrate 300, the plurality of solder balls 310 are arranged in a lattice shape and are distributed into 23 rows in the y direction, and up to 23 solder balls 310 are arranged in each row. The solder balls 310 coupled to the motor driver 110, the head drive IC 120, the serial flash memory 130, the DDR 140, the connectors 151, 152, 153, and 154, and the like are arranged at the outermost peripheral portion of the terminal mounting surface 301 or at a position close to the outermost peripheral portion. The plurality of solder balls 310 arranged at the outermost periphery have a wider arrangement interval in order to ensure a space through which wiring coupled to the solder ball 310 on the inner side passes. Further, on the terminal mounting surface 301, a power supply voltage is supplied to the plurality of solder balls 310 arranged in a region in the vicinity of the center surrounded by a broken line.

### 4. Functional Configuration of Integrated Circuit Chip

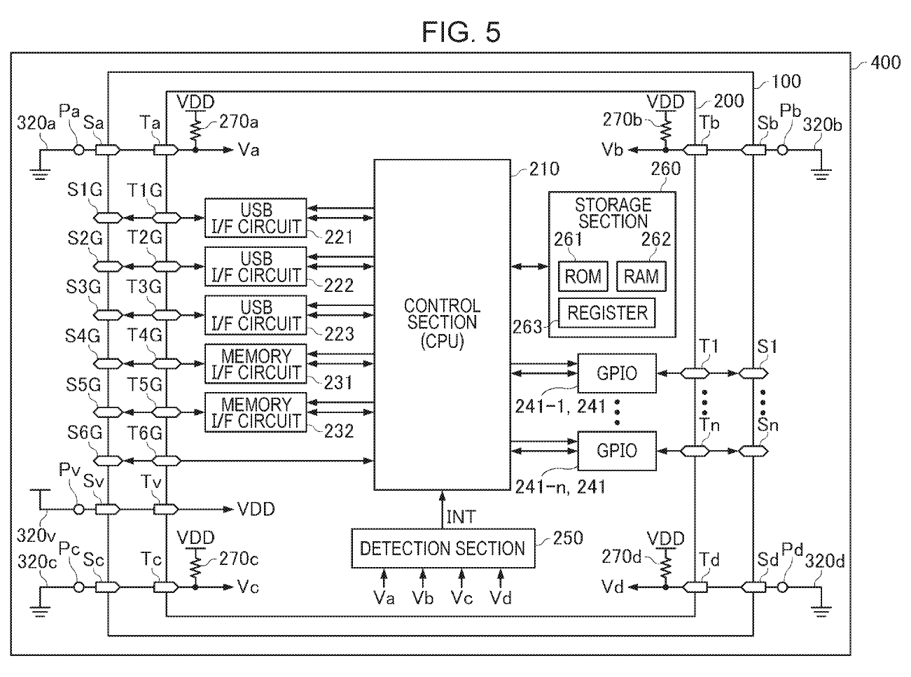

FIG. 5 is a functional block diagram of the integrated circuit chip 200. As shown in FIG. 5, the integrated circuit chip 200 includes a control section 210, USB interface circuits 221, 222, and 223, memory interface circuits 231 and 232, n GPIO 241-1 to 241-n, a detection section 250, a storage section 260, and resistors 270a, 270b, 270c, and 270d. GPIO is an abbreviation for General-Purpose Input/Output. The integrated circuit chip 200 may have a configuration in which some of the constituent elements shown in FIG. 5 are omitted or changed, or other constituent elements are added.

The USB interface circuit 221 is coupled to a group of terminals T1G including a plurality of terminals of the integrated circuit chip 200. The USB interface circuit 222 is coupled to a group of terminals T2G including a plurality of terminals of the integrated circuit chip 200. The USB interface circuit 223 is coupled to a group of terminals T3G including a plurality of terminals of the integrated circuit chip 200. The memory interface circuit 231 is coupled to a group of terminals T4G including a plurality of terminals of the integrated circuit chip 200. The memory interface circuit 232 is coupled to a group of terminals T5G including a plurality of terminals of the integrated circuit chip 200. The control section 210 is coupled to a group of terminals T6G including a plurality of terminals of the integrated circuit chip 200.

The groups of terminals T1G to T6G of the integrated circuit chip 200 are coupled to groups of terminals S1G to S6G of the semiconductor device 100, respectively. Each terminal included in the groups of terminals S1G to S6G of the semiconductor device 100 is the solder balls 310 provided on the terminal mounting surface 301. The group of terminals S1G of the semiconductor device 100 is coupled to PC2 via the connector 154. The group of terminals S2G of the semiconductor device 100 is coupled to the SD control IC 170 via the cable 72. The group of terminals S3G of the semiconductor device 100 is coupled to the wireless LAN module 64 via the cable 73. The group of terminals S4G of the semiconductor device 100 is coupled to the serial flash memory 130. The group of terminals S5G of the semiconductor device 100 is coupled to the DDR 140. The group of terminals S6G of the semiconductor device 100 is coupled to the LCD control IC 160.

The n GPIO 241-1 to 241-n are coupled to n terminals S1 to Sn of the semiconductor device 100, respectively. The n terminals T1 to Tn of the integrated circuit chip 200 are respectively coupled to the n terminals S1 to Sn of the semiconductor device 100. The terminals S1 to Sn of the semiconductor device 100 are the solder balls 310 provided on the terminal mounting surface 301.

The storage section 260 includes a ROM 261, a RAM 262, and a register 263. ROM is an abbreviation for Read Only Memory, and RAM is an abbreviation for Random Access Memory. The ROM 261 stores various programs and predetermined data. The RAM 262 is used as a work area of the control section 210, and stores programs and data read from the ROM 261 and data temporarily generated by the control section 210. The register 263 stores various kinds of setting data and the like.

The control section 210 performs various kinds of control, image processing, and the like. In the present embodiment, the control section 210 is a processor such as a CPU, and performs various types of control, image processing, and the like by executing a program (not shown) stored in the ROM 261. However, a portion of the processing of the control section 210 may be implemented by hardware.

Specifically, the control section 210 performs various kinds of control on the motor driver 110, the head drive IC 120, the scanner module 63, and the LCD control IC 160.

The control section 210 performs USB communication with the PC2 by controlling the USB interface circuit 221. The control section 210 performs USB communication with the SD control IC 170 by controlling the USB interface circuit 222. The control section 210 performs USB communication with the wireless LAN module 64 by controlling the USB interface circuit 223. Further, the control section 210 transmits the image data to the LCD control IC 160.

In addition, the control section 210 writes and reads data to and from the serial flash memory 130 by controlling the memory interface circuit 231. The control section 210 writes and reads data to and from the DDR 140 by controlling the memory interface circuit 232.

For example, the control section 210 receives image data for printing from the PC2 via the USB interface circuit 221, and writes the image in the serial flash memory 130 or the DDR 140. Further, for example, the control section 210 receives the image data stored in the SD card 3 from the SD control IC 170 via the USB interface circuit 222, and writes the image data in the serial flash memory 130 or the DDR 140. Further, for example, the control section 210 receives image data from the wireless LAN module 64 via the USB interface circuit 223, and writes the image data to the serial flash memory 130 or the DDR 140. Further, for example, the control section 210 acquires scan data from the scanner module 63, performs image processing on the scan data to generate image data, and writes the image data in the serial flash memory 130 or the DDR 140.

Further, for example, the control section 210 performs image processing on the scan data and writes the generated image data to the serial flash memory 130 or the DDR 140.

In addition, for example, the control section 210 reads image data for printing from the serial flash memory 130 or the DDR 140, performs image processing for printing to generate print data, and outputs the print data to the head drive IC 120. In addition, for example, the control section 210 reads the image data from the serial flash memory 130 or the DDR 140 and transmits the image data to the PC2 via the USB interface circuit 221. Further, for example, the control section 210 reads the image data from the serial flash memory 130 or the DDR 140, and transmits the image data to the SD control IC 170 via the USB interface circuit 222. In addition, for example, the control section 210 reads the image data from the serial flash memory 130 or the DDR 140, and transmits the image data to the wireless LAN module 64 via the USB interface circuit 223.

Further, the control section 210 controls input and output of each of the GPIO 241-1 to 241-n. Specifically, the control section 210 controls each of the GPIO 241-1 to 241-n to be any one of an input-output circuit, an input circuit, and an output circuit. For example, the control section 210 may control the GPIO 241-k and the GPIO 241-l among the GPIO 241-3 to 241-n such that each serves as an output circuit, and may output control signals from terminals Tk and Tl to the power supply circuit 190 and the reset IC 192, respectively.

As shown in FIG. 5, a terminal Tv of the integrated circuit chip 200 is coupled to a terminal Sv of the semiconductor device 100. The terminal Sv of the semiconductor device 100 is coupled to a pad Pv provided on the printed circuit board 400. The pad Pv is one of the plurality of pads 410 shown in FIG. 3. In the printed circuit board 400, the pad Pv is coupled to wiring 320v. The wiring 320v is power supply wiring, and a power supply voltage VDD of several volts generated by the power supply circuit 190 shown in FIG. 2 is supplied to the semiconductor device 100 from the terminal Sv. Each portion of the integrated circuit chip 200 operates by being supplied with the power supply voltage VDD.

The terminals Ta, Tb, Tc, and Td of the integrated circuit chip 200 are coupled to the terminals Sa, Sb, Sc, and Sd of the semiconductor device 100. The terminals Sa, Sb, Sc, and Sd of the semiconductor device 100 are solder balls 310 provided on the terminal mounting surface 301, respectively, and are coupled to pads Pa, Pb, Pc, and Pd provided on the printed circuit board 400. Each of the pads Pa, Pb, Pc, and Pd is one of the plurality of pads 410 shown in FIG. 3. In the printed circuit board 400, the pads Pa, Pb, Pc, and Pd are coupled to the wirings 320a, 320b, 320c, and 320d, respectively. The wirings 320a, 320b, 320c, and 320d are constant potential wirings having a constant potential, for example, a ground potential.

The terminals Ta, Tb, Tc, and Td of the integrated circuit chip 200 are coupled to a supply line of the power supply voltage VDD via respective resistors 270a, 270b, 270c, and 270d. That is, the resistors 270a, 270b, 270c, and 270d function as a pull-up resistor. Therefore, the terminals Sa and Ta are at the ground potential when the coupling between the terminal Sa and the pad Pa is normal, but are pulled up through the resistor 270a to the power supply potential when the coupling failure occurs. Similarly, the terminals Sb and Tb are at the ground potential when the coupling between the terminal Sb and the pad Pb is normal, but are pulled up through the resistor 270b to the power supply potential when the coupling failure occurs. Similarly, the terminals Sc and Tc are at the ground potential when the coupling between the terminal Sc and the pad Pc is normal, but are pulled up through the resistor 270c to the power supply potential when the coupling failure occurs. Similarly, the terminals Sd and Td are at the ground potential when the coupling between the terminal Sd and the pad Pd is normal, but are pulled up through the resistor 270d to the power supply potential when the coupling failure occurs.

In the present embodiment, the control section 210 functions as a determination section that determines the presence or absence of a coupling failure between the semiconductor device 100 and the printed circuit board 400 based on the potential of the terminals Sa, Sb, Sc, and Sd of the semiconductor device 100, that is, the potential of the terminals Ta, Tb, Tc, and Td of the integrated circuit chip 200. In other words, the control section 210 determines that the coupling between the semiconductor device 100 and the printed circuit board 400 is normal when the potentials of all the terminals Ta, Tb, Tc, and Td are at a low level, and determines that the coupling between the semiconductor device 100 and the printed circuit board 400 is a failure when the potential of at least one of the terminals Ta, Tb, Tc, and Td is at a high level.

In the present embodiment, the detection section 250 outputs an interrupt signal INT to the control section 210, which is a determination section, when at least one of the potentials of the terminals Sa, Sb, Sc, and Sd, that is, the potentials of the terminals Ta, Tb, Tc, and Td of the integrated circuit chip 200, changes from a low level to a high level. When the interrupt signal INT is input, the control section 210 determines that a coupling failure has occurred between the semiconductor device 100 and the printed circuit board 400. In this way, since the control section 210 does not need to determine the presence or absence of a coupling failure until the interrupt signal INT is input, other processing can be preferentially performed.

The control section 210 performs predetermined processing when a coupling failure is detected. For example, when it is determined that a coupling failure has occurred, the control section 210 may stop the supply of power from the power supply circuit 190 to the motor driver 110 and the motor 61. For example, the recording device 13 may include a transport motor that transports a sheet, which is a medium, as the motor 61, and the control section 210 may stop the supply of power from the power supply circuit 190 to the transport motor when it is determined that the coupling failure has occurred. When the coupling failure between the semiconductor device 100 and the printed circuit board 400 occurs, there is a concern that the recording device 13 may not perform normal printing. Therefore, by stopping the supply of power to the transport motor, the sheet is not wastefully consumed.

Further, for example, the control section 210 may transmit a control signal to the reset IC 192 when it is determined that the coupling failure has occurred, and the reset IC 192 may receive the control signal and reset the semiconductor device 100. When the semiconductor device 100 is reset, the detection section 250 outputs the interrupt signal INT to the control section 210 again, and the control section 210 detects a coupling failure and transmits a control signal to the reset IC 192 again. That is, once the control section 210 detects the coupling failure, the reset of the semiconductor device 100 is repeated. Therefore, various functions of the semiconductor device 100 are stopped, and the possibility of a malfunction due to the coupling failure is reduced.

The control section 210 may determine the presence or absence of a coupling failure between the semiconductor device 100 and the printed circuit board 400 based on the logic level of the potential of the terminals Sa, Sb, Sc, and Sd at a timing immediately after the terminal Sv of the semiconductor device 100 reaches the power supply potential as a result of the power supply circuit 190 starting to supply the power supply voltage VDD to the semiconductor device 100. That is, the control section 210 may determine the presence or absence of a coupling failure each time startup is performed. In this way, the control section 210 can promptly detect and cope with a coupling failure due to aging deterioration.

The terminals Sa, Sb, Sc, and Sd are preferably four solder balls 310 arranged at the outermost periphery of the base substrate 300, which are likely to cause coupling failure due to aging deterioration, among the plurality of solder balls 310 provided on the base substrate 300. Further, it is preferable that the terminals Sa, Sb, Sc, and Sd are four solder balls 310 arranged at four corners of the base substrate 300, which are likely to first cause the coupling failure due to aging deterioration.

For example, as shown in FIG. 4, the terminal Sa is a solder ball 310a closest to the corner where the side 302 and the side 304 of the base substrate 300 intersect. Therefore, in the y direction from the side 303 toward the side 302, none of the plurality of solder balls 310, which are the plurality of terminals of the semiconductor device 100, is arranged between the terminal Sa and the side 302. In addition, in the -x direction from the side 305 toward the side 304, none of the plurality of solder balls 310, which are the plurality of terminals of the semiconductor device 100, is arranged between the terminal Sa and the side 304.

As shown in FIG. 4, the terminal Sb is a solder ball 310b closest to the corner where the side 302 and the side 305 of the base substrate 300 intersect. Therefore, in the x direction from the side 304 toward the side 305, none of the plurality of terminals of the semiconductor device 100 is arranged between the terminal Sb and the side 305. In the y direction from the side 303 toward the side 302, none of the plurality of terminals of the semiconductor device 100 is arranged between the terminal Sb and the side 302.

As shown in FIG. 4, the terminal Sc is a solder ball 310c closest to the corner where the side 303 and the side 304 of the base substrate 300 intersect. Therefore, in the -x direction from the side 305 toward the side 304, none of the plurality of terminals of the semiconductor device 100 is arranged between the terminal Sc and the side 304. In the -y direction from the side 302 toward the side 303, none of the plurality of terminals of the semiconductor device 100 is arranged between the terminal Sc and the side 303.

As shown in FIG. 4, the terminal Sd is a solder ball 310d closest to the corner where the side 303 and the side 305 of the base substrate 300 intersect. Therefore, in the -y direction from the side 302 toward the side 303, none of the plurality of terminals of the semiconductor device 100 is arranged between the terminal Sd and the side 303. In the x direction from the side 304 toward the side 305, none of the plurality of terminals of the semiconductor device 100 is arranged between the terminal Sd and the side 305.

However, if the power supply voltage VDD is not supplied to the semiconductor device 100, the control section 210 cannot determine the coupling failure between the terminals Sa, Sb, Sc, and Sd and the pads Pa, Pb, Pc, and Pd. Therefore, it is preferable that the terminal Sv through which the power supply voltage VDD is shared is arranged at a position where the coupling failure is less likely to occur due to the aging deterioration earlier than the terminals Sa, Sb, Sc, and Sd among the plurality of solder balls 310 provided on the base substrate 300. That is, the terminal Sv is preferably arranged closer to the center than each of the terminals Sa, Sb, Sc, and Sd in the base substrate 300.

For example, in FIG. 4, since the terminal Sa is arranged near the side 302, the shortest distance Ds1 between the terminal Sa and the side 302 is smaller than the shortest distance Ds2 between the terminal Sa and the side 303. Therefore, in a relationship between the arrangement of the terminal Sa and the arrangement of the terminal Sv, it is preferable that the shortest distance Dv1 between the terminal Sv and the side 302 be larger than the shortest distance Ds1 between the terminal Sa and the side 302, and the shortest distance Dv2 between the terminal Sv and the side 303 be larger than the shortest distance Ds1 between the terminal Sa and the side 302.

For example, in FIG. 4, since the terminal Sa is arranged near the side 304, the shortest distance Ds3 between the terminal Sa and the side 304 is smaller than the shortest distance Ds4 between the terminal Sa and the side 305. Therefore, in a relationship between the arrangement of the terminal Sa and the arrangement of the terminal Sv, it is preferable that the shortest distance Dv3 between the terminal Sv and the side 304 be larger than the shortest distance Ds3 between the terminal Sa and the side 304, and the shortest distance Dv4 between the terminal Sv and the side 305 be larger than the shortest distance Ds3 between the terminal Sa and the side 304.

The relationship between the arrangement of each of the terminals Sb, Sc, and Sd and the arrangement of the terminal Sv is the same as the relationship between the arrangement of the terminal Sa and the arrangement of the terminal Sv, and as a result, the terminal Sv is preferably arranged in a region near the center of the base substrate 300 surrounded by a broken line in FIG. 4, which is away from the four corners of the base substrate 300.

In FIGS. 4 and 5, although the four terminals Sa, Sb, Sc, and Sd for detecting the coupling failure with the printed circuit board 400 are provided in the semiconductor device 100, it is sufficient that at least one of the terminals Sa, Sb, Sc, and Sd is provided.

### 5. Layout of Pads and Wiring of Printed Circuit Board

By mounting the integrated circuit chip 200 in the small package 330, the size and cost of the semiconductor device 100 can be reduced. However, in the small package 330, spacing between the solder balls 310 is narrowed, and spacing between the pads 410 provided on the printed circuit board 400 is also narrowed. Therefore, it is likely to be difficult to extend a large number of wirings coupled to the respective pads 410 to the outside of the mounting region of the semiconductor device 100 through the spaces between the large number of pads 410. Therefore, in the present embodiment, the shape or the like of a portion of the pads 410 is devised in order to ensure a space for passing each wiring in the printed circuit board 400.

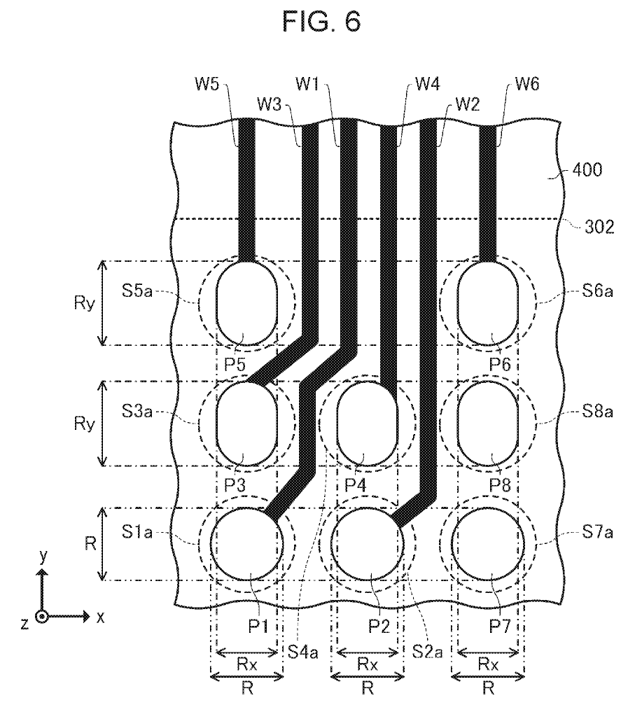

FIG. 6 is a plan view of a portion of the printed circuit board 400 as viewed from the +z side. As shown in FIG. 3, a plurality of pads 410 are provided on the printed circuit board 400, and as shown in FIG. 6, pads P1, P2, P3, P4, P5, P6, P7, and P8 are included in the plurality of pads 410. Each of the plurality of pads 410 is provided at a position corresponding to each of the plurality of solder balls 310, which are the plurality of terminals of the semiconductor device 100, and each solder ball 310 is coupled to each pad 410, whereby the semiconductor device 100 is mounted on the printed circuit board 400. When the semiconductor device 100 is mounted on the printed circuit board 400, each of the plurality of pads 410 provided on the printed circuit board 400 is electrically coupled to any of the terminals of the semiconductor device 100 and any of the terminals of the integrated circuit chip 200.

As shown in FIG. 6, the pads P1, P2, P3, P4, P5, P6, P7, and P8 are coupled to the terminals S1a, S2a, S3a, S4a, S5a, S6a, S7a, and S8a of the semiconductor device 100, respectively.

The pads P1, P2, and P7 are circular, respectively, and the pads P3, P4, P5, P6, and P8 are oval, respectively. The oval has a diameter Ry in the y direction that is larger than a diameter R of the circle, and a diameter Rx in the x direction that is smaller than the diameter R of the circle. That is, the pads P3, P4, P5, P6, and P8 are oval extending in the y direction, and the area of each of the pads P3, P4, P5, P6, and P8 are equal to the area of each of the pads P1, P2, and P7. Therefore, the coupling strength between each of the terminals S3a, S4a, S5a, S6a, S7a, and S8a and each of the pads P3, P4, P5, P6, and P8 can be made equal to the coupling strength between each of the terminals S1a, S2a, and S7a and each of the pads P1, P2, and P7. In the present embodiment, the shape of the pads P3, P4, P5, P6, and P8 is described as an oval, but the shape of the pads P3, P4, P5, P6, and P8 may be an ellipse having approximately the same area.

In FIG. 6, the side 302 of the terminal mounting surface 301 is indicated by a broken line. That is, the pad P5 and the pad P6 are arranged along the side 302. The pad P5 and the pad P6 are adjacent to each other in the x direction from the side 304 to the side 305. In the y direction from the side 303 toward the side 302, none of the plurality of pads 410 is arranged between the pad P5 and the side 302. Similarly, in the y direction, none of the plurality of pads 410 is arranged between the pad P6 and the side 302. That is, each of the pads P5 and P6 is coupled to the outermost solder ball 310 provided on the terminal mounting surface 301.

In the x direction, the pad P3 and the pad P4 are adjacent to each other, and the pad P4 and the pad P8 are adjacent to each other. Further, in the x direction, the pad P1 and the pad P2 are adjacent to each other, and the pad P2 and the pad P7 are adjacent to each other.

In the y direction, the pad P1, the pad P3, and the pad P5 at least partially overlap each other. In the y direction, the pad P2 and the pad P4 at least partially overlap each other. Further, in the y direction, the pad P7, the pad P8, and the pad P6 at least partially overlap each other. That is, between the pad P5 and the pad P6, the pad 410 is not arranged on the -y side of the pad P4. Therefore, the shortest distance between the pad P5 and the pad P6 is longer than the shortest distance between the pad P3 and the pad P4 and the shortest distance between the pad P4 and the pad P8. Since the pads P3, P4, and P8 are oval and the pads P1, P2, and P7 are circular, the shortest distance between the pad P3 and the pad P4 and the shortest distance between the pad P4 and the pad P8 are longer than the shortest distance between the pad P1 and the pad P2 and the shortest distance between the pad P2 and the pad P7. Further, as described above, since the pads P5 and P6 are oval extending in the y direction, a wide space is provided between the pad P5 and the pad P6.

As shown in FIG. 6, the printed circuit board 400 is provided with a plurality of wirings including wirings W1, W2, W3, W4, W5, and W6. The wirings W1, W2, W3, W4, W5, and W6 are coupled to the pads P1, P2, P3, P4, P5, and P6, respectively.

The wiring W5 extends in the y direction from the pad P5. The wiring W1 extends in the y direction from the pad P1, passing between the pad P3 and the pad P4. The wiring W3 extends in the y direction from the pad P3, passing between the pad P5 and the wiring W1, and further passing between the wiring W5 and the wiring W1. The wiring W2 extends in the y direction from the pad P2, passing between the pad P4 and the pad P5. The wiring W4 extends in the y direction from the pad P4, passing between the wiring W1 and the wiring W2. The wiring W6 extends in the y direction from the pad P6. In other words, the wiring W1 passes between the pad P3 and the pad P4, the wiring W2 passes between the pad P4 and the pad P8, the wirings W1 and W3 pass between the pad P4 and the pad P5, and the wirings W1, W2, W3, and W4 pass between the pad P5 and the pad P6.

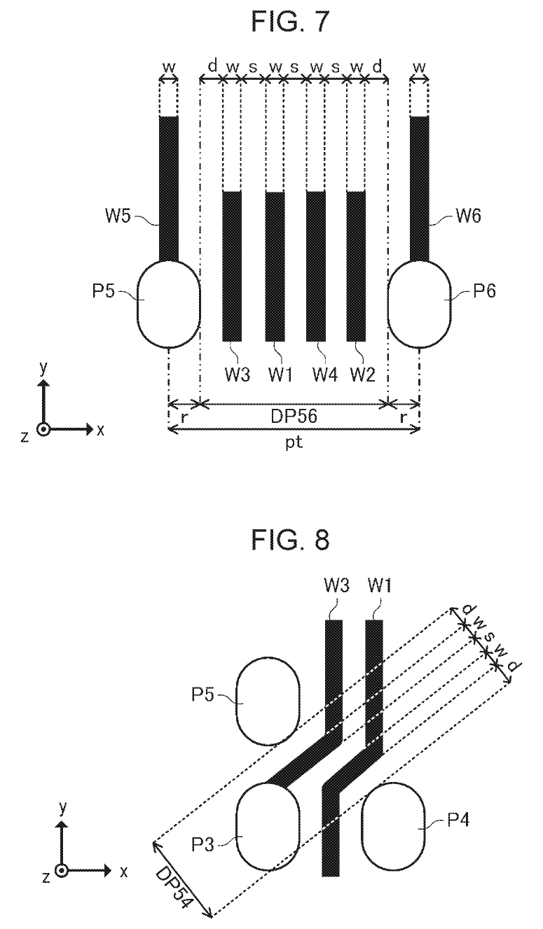

There are certain constraints on the arrangement of the pads P1 to P8 and the wirings W1 and W2, and it is necessary to pass the four wirings W1 to W4 between the pad P5 and the pad P6 while satisfying the constraints. FIG. 7 is a diagram showing only a portion of the pads P5 and P6 and the wirings W1 to W6. The pitch of the pads P1 to P8 is determined by the pitch of the solder balls 310, and the pitch pt between the pad P5 and the pad P6 is, for example, 1 mm. On the other hand, due to manufacturing limits and the like, a minimum value is determined for a wiring width w, a wiring spacing s, a pad-to-wiring spacing d, and the pad radius r. For example, the minimum value of the wiring width w is 0.080 mm, the minimum value of wiring spacing s is 0.090 mm, the minimum value of the pad-to-wiring spacing d is 0.100 mm, and the minimum value of the pad radius r is 0.100 mm.

Here, since the minimum value of the wiring width w is smaller than the minimum value of the wiring spacing s, between the pad P5 and the pad P6, the width of the wiring W1, the width of the wiring W2, the width of the wiring W3, and the width of the wiring W4 can be made smaller than the spacing between the wiring W3 and the wiring W1, the spacing between the wiring W1 and the wiring W4, and the spacing between the wiring W4 and the wiring W2. In addition, since the minimum value of the wiring spacing s is smaller than the minimum value of the pad-to-wiring spacing d, the spacing between the wiring W3 and the wiring W1, the spacing between the wiring W1 and the wiring W4, and the spacing between the wiring W4 and the wiring W2 can be made smaller than the spacing between the pad P5 and the wiring W3 and the spacing between the pad P6 and the wiring W2.

For example, when the widths of the wirings W1, W2, W3, and W4 are each set to 0.080 mm, which is the minimum value of the wiring width w, the spacing between the wiring W3 and the wiring W1, the spacing between the wiring W1 and the wiring W4, and the spacing between the wiring W4 and the wiring W2 are each set to 0.090 mm, which is the minimum value of the wiring spacing s, and the spacing between the pad P5 and the wiring W3 and the spacing between the pad P6 and the wiring W2 are each set to 0.100 mm, which is the minimum value of the pad-to-wiring spacing d, a distance DP56 between the pad P5 and the pad P6 is 0.080 mm × 4 + 0.090 mm × 3 + 0.100 mm × 2 = 0.790 mm. Therefore, when each of the radii of the pads P5 and P6 is set to 0.100 mm, which is the minimum value of the pad radius r, the distance between the center of the pad P5 and the center of the pad P6 are 0.790 mm + 0.100 mm × 2 = 0.990 mm and fall within 1 mm which is the pitch pt. Therefore, it is possible to pass the four wirings W1 to W4 between the pad P5 and the pad P6. In this case, since a difference between 1 mm, which is the pitch pt, and 0.990 mm, which is the distance between the center of the pad P5 and the center of the pad P6, is 0.010 mm, for example, when the spacing between the wiring W3 and the wiring W1 is set to 0.093 mm, the spacing between the wiring W1 and the wiring W4 is set to 0.093 mm, the spacing between the wiring W4 and the wiring W2 is set to 0.094 mm, the distance between the center of the pad P5 and the center of the pad P6 can be made to coincide with 1 mm, which is the pitch pt.

Further, it is also necessary to pass the two wirings W1 and W3 between the pad P5 and the pad P4 while satisfying the constraints. FIG. 8 is a diagram showing only a portion of the pads P3, P4, and P5 and the wirings W1 and W3.

As described above, since the minimum value of the wiring width w is smaller than the minimum value of the wiring spacing s, the width of the wiring W3 and the width of the wiring W1 can be made smaller than the spacing between the wiring W3 and the wiring W1. In addition, since the minimum value of the wiring spacing s is smaller than the minimum value of the pad-to-wiring spacing d, the spacing between the wiring W3 and the wiring W1 can be made smaller than the spacing between the pad P5 and the wiring W3 and the spacing between the pad P4 and the wiring W1.

For example, when the widths of the wirings W1 and W3 are each set to 0.080 mm, which is the minimum value of the wiring width w, the spacing between the wiring W3 and the wiring W1 is set to 0.090 mm, which is the minimum value of the wiring spacing s, and the spacing between the pad P5 and the wiring W3 and the spacing between the pad P4 and the wiring W1 are each set to 0.100 mm, which is the minimum value of the pad-to-wiring spacing d, the distance DP54 between the pad P5 and the pad P4 is 0.080 mm × 2 + 0.090 mm × 1 + 0.100 mm × 2 = 0.45 mm. In practice, when the pads P3, P4, and P5 are arranged at the pitch pt of the 1 mm, since the distance DP54 between the pad P5 and the pad P4 is 0.4557 mm, it is possible to pass the two wirings W1 and W3 between the pad P4 and the pad P5.

In the arrangement of the pads P1 to P8 and the wirings W1 and W2 shown in FIG. 6, the shortest distance between the pad P5 and the wiring W3, the shortest distance between the pad P3 and the wiring W1, the shortest distance between the pad P4 and the wiring W1, the shortest distance between the pad P4 and the wiring W2, the shortest distance between the pad P6 and the wiring W2, the shortest distance between the pad P7 and the wiring W2, and the shortest distance between the pad P8 and the wiring W2 are larger than the shortest distance between the wiring W3 and the wiring W1, the shortest distance between the wiring W1 and the wiring W4, and the shortest distance between the wiring W4 and the wiring W2. For example, the shortest distance between the pad P5 and the wiring W3, the shortest distance between the pad P3 and the wiring W1, the shortest distance between the pad P4 and the wiring W1, the shortest distance between the pad P4 and the wiring W2, the shortest distance between the pad P6 and the wiring W2, the shortest distance between the pad P7 and the wiring W2, and the shortest distance between the pad P8 and the wiring W2 are 0.100 mm, which is the minimum value of the pad-to-wiring spacing d. On the other hand, the shortest distance between the wiring W3 and the wiring W1, the shortest distance between the wiring W1 and the wiring W4, and the shortest distance between the wiring W4 and the wiring W2 are 0.090 mm, which is the minimum value of the wiring spacing s. In this way, by increasing the shortest distance between each pad and each wiring, the arrangement region of the solder ball 310 coupled to each pad is sufficiently ensured.

The terminal S1a is an example of a "first terminal", the terminal S2a is an example of a "second terminal", the terminal S3a is an example of a "third terminal", the terminal S4a is an example of a "fourth terminal", the terminal S5a is an example of a "fifth terminal", the terminal S6a is an example of a "sixth terminal". The pad P1 is an example of a "first pad", the pad P2 is an example of a "second pad", the pad P3 is an example of a "third pad", the pad P4 is an example of a "fourth pad", the pad P5 is an example of a "fifth pad", and the pad P6 is an example of a "sixth pad". The wiring W1 is an example of a "first wiring", the wiring W2 is an example of a "second wiring", the wiring W3 is an example of a "third wiring", and the wiring W4 is an example of a "fourth wiring". The base substrate 300 is an example of an "integrated circuit substrate". The side 302 is an example of a "first side", the side 303 is an example of a "second side", the side 304 is an example of a "third side", and the side 305 is an example of a "fourth side". The y direction is an example of a "first direction", and the x direction is an example of a "second direction".

### 6. Operational Effects

As described above, according to the electronic apparatus 1 of the present embodiment, when at least one of the terminals Sa, Sb, Sc, and Sd provided on the base substrate 300 of the semiconductor device 100 is peeled off from the printed circuit board 400, the potential of at least one of the terminals Sa, Sb, Sc, and Sd changes. Therefore, the control section 210 can detect the coupling failure between the semiconductor device 100 and the printed circuit board 400 based on the potential. Since the semiconductor device 100 incorporates the control section 210, the inspection of the coupling failure can be performed at any timing. Therefore, the coupling failure between the semiconductor device 100 and the printed circuit board 400 caused by the aging deterioration can be promptly detected. Further, since the semiconductor device 100 incorporates the control section 210, it is not necessary to mount a circuit for detecting the coupling failure between the semiconductor device 100 and the printed circuit board 400 on the printed circuit board 400, whereby the cost of the printed circuit board 400 can be reduced.

In addition, according to the electronic apparatus 1 of the present embodiment, since the terminals Sa, Sb, Sc, and Sd are provided at the four corners of the base substrate 300 where a probability of coupling failure is highest when the base substrate 300 of the semiconductor device 100 is warped due to the aging deterioration, the detection accuracy of the coupling failure can be improved.

According to the electronic apparatus 1 of the present embodiment, the terminal Sv coupled to the power supply wiring is provided in the central region in the base substrate 300 of the semiconductor device 100. Therefore, the possibility that the terminal Sv peels off before the terminals Sa, Sb, Sc, and Sd is low. Therefore, a situation in which the power supply voltage VDD is not supplied to the integrated circuit chip 200 and the control section 210 cannot determine a coupling failure is unlikely to occur. In addition, since the power supply voltage VDD is supplied from a position close to the center of the integrated circuit chip 200 through the terminal Sv, a voltage drop of the power supply voltage VDD supplied to each portion of the integrated circuit chip 200 becomes small, and the possibility that the integrated circuit chip 200 malfunctions is reduced. Further, in the printed circuit board 400, since the pad Pv coupled to the terminal Sv is arranged further inward than the other pads, the pad Pv does not hinder the lead-out of wiring from the other pads.

In the electronic apparatus 1 according to the present embodiment, as shown in FIG. 6, in the printed circuit board 400, the pads P5 and P6 are arranged closest to the side 302 of the base substrate 300, the pads P3, P4, and P8 are arranged at positions next closest to the side 302, and the pads P1, P2, and P7 are arranged at positions further next closest to the side 302. Further, in the printed circuit board 400, the pads P1 to P8 are arranged in a lattice shape, and a space between the pad P3 and the pad P4 and a space between the pad P4 and the pad P8 are wider than a space between the pad P1 and the pad P2 and a space between the pad P2 and the pad P7, and a space between the pad P5 and the pad P6 is wider than a space between the pad P3 and the pad P4 and a space between the pad P4 and the pad P8. Therefore, according to the electronic apparatus 1 of the present embodiment, in the printed circuit board 400, the four wirings W1 to W4 respectively coupled to the pads P1 to P4 can be led out through the space between the pad P3 and the pad P4, the space between the pad P4 and the pad P8, and the space between the pad P5 and the pad P6.

In addition, according to the electronic apparatus 1 of the present embodiment, since it is possible to widen the spacing between the pad P5 and the pad P6 by forming the pads P5 and P6 in an oval shape, the wirings W1 to W4 can be easily led out through the spacing between the pad P5 and the pad P6. In addition, since the spacing between the pad P3 and the pad P4 can be widen by forming the pads P3 and P4 in an oval shape, the wiring W1 can be easily led out through the spacing between the pad P3 and the pad P4. Further, since the spacing between the pad P4 and the pad P8 can be widen by forming the pad P8 in an oval shape, the wiring W2 can be easily led out through the spacing between the pad P4 and the pad P8.

The present disclosure is not limited to the present embodiment, and various modifications can be made within the scope of the spirit of the present disclosure.

For example, in the present embodiment, the package 330 of the semiconductor device 100 has been described as a ball grid array (BGA), but the package 330 may be a surface-mounted package other than the BGA, such as a system in package (SiP), a land grid array (LGA), or a wafer process package (WPP). For example, when the package 330 is an LGA, the terminals of the semiconductor device 100 are lands provided on the package 330, and the lands, which are the terminals of the semiconductor device 100, and the pads 410 provided on the printed circuit board 400 are coupled by the solder balls 310.

Although the embodiments have been described above, the present disclosure is not limited to these embodiments, and can be implemented in various aspects without departing from the scope of the present disclosure. For example, the above-described embodiments may be appropriately combined.

The present disclosure includes configurations that are substantially the same as the configurations described in the embodiments, for example, a configuration having the same functions, methods, and results as those described in the embodiments, or a configuration having the same objects and effects as those described in the embodiments. The present disclosure includes configurations in which non-essential portions of the configurations described in the embodiments are replaced. In addition, the present disclosure includes configurations that achieve the same operational effects or configurations that can achieve the same objects as those of the configurations described in the embodiments. In addition, the present disclosure includes configurations in which a known technique is added to the configurations described in the embodiments.

The following contents are derived from the above-described embodiments.

According to one aspect, an electronic apparatus includes a printed circuit board, and a semiconductor device mounted on the printed circuit board, in which the semiconductor device includes an integrated circuit chip, and an integrated circuit substrate on which the integrated circuit chip is mounted, the integrated circuit substrate is provided with a plurality of terminals, the printed circuit board is provided with a plurality of pads, each of the plurality of terminals is coupled to each of the plurality of pads, the plurality of terminals include a first terminal, a second terminal, a third terminal, a fourth terminal, a fifth terminal, and a sixth terminal, the plurality of pads include a first pad, a second pad, a third pad, a fourth pad, a fifth pad, and a sixth pad, the first terminal is coupled to the first pad, the second terminal is coupled to the second pad, the third terminal is coupled to the third pad, the fourth terminal is coupled to the fourth pad, the fifth terminal is coupled to the fifth pad, the sixth terminal is coupled to the sixth pad, the integrated circuit substrate has a first side, a second side facing the first side, a third side, and a fourth side facing the third side, the fifth pad and the sixth pad are arranged along the first side, in a first direction from the second side toward the first side, none of the plurality of pads is arranged between the fifth pad and the first side, in the first direction, none of the plurality of pads is arranged between the sixth pad and the first side, in the first direction, the first pad, the third pad, and the fifth pad at least partially overlap, in a second direction from the third side toward the fourth side, the fifth pad and the sixth pad are adjacent to each other, in the second direction, the third pad and the fourth pad are adjacent to each other, in the second direction, the first pad and the second pad are adjacent to each other, a shortest distance between the third pad and the fourth pad is longer than a shortest distance between the first pad and the second pad, and a shortest distance between the fifth pad and the sixth pad is longer than the shortest distance between the third pad and the fourth pad.

In the electronic apparatus, on the printed circuit board, the fifth pad and the sixth pad are arranged closest to the first side of the integrated circuit substrate, the third pad and the fourth pad are arranged at positions next closest to the first side, and the first pad and the second pad are arranged at positions further next closest to the first side. Further, in the printed circuit board, the first pad to the sixth pad are arranged in a lattice shape, a space between the third pad and the fourth pad is wider than a space between the first pad and the second pad, and a space between the fifth pad and the sixth pad is wider than a space between the third pad and the fourth pad. Therefore, according to the electronic apparatus, in the printed circuit board, wirings respectively coupled to the first pad to the fourth pad can be led out through the space between the third pad and the fourth pad and the space between the fifth pad and the sixth pad.

In one aspect of the electronic apparatus, the printed circuit board may be provided with first wiring coupled to the first pad, second wiring coupled to the second pad, third wiring coupled to the third pad, and fourth wiring coupled to the fourth pad, and the first wiring, the second wiring, the third wiring, and the fourth wiring may pass between the fifth pad and the sixth pad.

According to the electronic apparatus, in the printed circuit board, four wirings respectively coupled to the first pad to the fourth pad can be led out through the space between the fifth pad and the sixth pad.

In one aspect of the electronic apparatus, the third pad, the fourth pad, the fifth pad, and the sixth pad may be oval, respectively.

According to the electronic apparatus, since the spacing between the fifth pad and the sixth pad can be widened by forming the fifth pad and the sixth pad in an oval shape, it is easy to lead out the wirings respectively coupled to the first pad to the fourth pad through the space between the fifth pad and the sixth pad. In addition, since the spacing between the third pad and the fourth pad can be widened by forming the third pad and the fourth pad in an oval shape, the wiring coupled to the first pad can be easily led out through the space between the third pad and the fourth pad.

In one aspect of the electronic apparatus, the first pad and the second pad may be circular, respectively, and the oval may have a diameter in the first direction larger than a diameter of the circle and a diameter in the second direction smaller than the diameter of the circle.

According to the electronic apparatus, since the areas of the oval third to sixth pads can be made equal to the areas of the circular first and second pads, the coupling strength between each of the third to sixth terminals and each of the third to sixth pads can be made equal to the coupling strength between the first terminal and the first pad and the coupling strength between the second terminal and the second pad.

In one aspect of the electronic apparatus, between the fifth pad and the sixth pad, a width of the first wiring, a width of the second wiring, a width of the third wiring, and a width of the fourth wiring may be smaller than spacing between the third wiring and the first wiring, spacing between the first wiring and the fourth wiring, and spacing between the fourth wiring and the second wiring.

In one aspect of the electronic apparatus, the first wiring and the third wiring may pass between the fourth pad and the fifth pad.

In one aspect of the electronic apparatus, a shortest distance between the fifth pad and the third wiring, a shortest distance between the third pad and the first wiring, a shortest distance between the fourth pad and the first wiring, a shortest distance between the fourth pad and the second wiring, and a shortest distance between the sixth pad and the second wiring may be larger than a shortest distance between the third wiring and the first wiring, a shortest distance between the first wiring and the fourth wiring, and a shortest distance between the fourth wiring and the second wiring.

What is claimed is:

1. An electronic apparatus comprising:
a printed circuit board; and
a semiconductor device mounted on the printed circuit board, wherein
the semiconductor device includes
an integrated circuit chip, and
an integrated circuit substrate on which the integrated circuit chip is mounted,
the integrated circuit substrate is provided with a plurality of terminals,
the printed circuit board is provided with a plurality of pads,
each of the plurality of terminals is coupled to each of the plurality of pads,
the plurality of terminals include a first terminal, a second terminal, a third terminal, a fourth terminal, a fifth terminal, and a sixth terminal,
the plurality of pads include a first pad, a second pad, a third pad, a fourth pad, a fifth pad, and a sixth pad,
the first terminal is coupled to the first pad,
the second terminal is coupled to the second pad,
the third terminal is coupled to the third pad,
the fourth terminal is coupled to the fourth pad,
the fifth terminal is coupled to the fifth pad,
the sixth terminal is coupled to the sixth pad,
the integrated circuit substrate has a first side, a second side facing the first side, a third side, and a fourth side facing the third side,
the fifth pad and the sixth pad are arranged along the first side,
in a first direction from the second side toward the first side, none of the plurality of pads is arranged between the fifth pad and the first side,
in the first direction, none of the plurality of pads is arranged between the sixth pad and the first side,
in the first direction, the first pad, the third pad, and the fifth pad at least partially overlap,
in a second direction from the third side toward the fourth side, the fifth pad and the sixth pad are adjacent to each other,
in the second direction, the third pad and the fourth pad are adjacent to each other,
in the second direction, the first pad and the second pad are adjacent to each other,
a shortest distance between the third pad and the fourth pad is longer than a shortest distance between the first pad and the second pad, and
a shortest distance between the fifth pad and the sixth pad is longer than the shortest distance between the third pad and the fourth pad.

2. The electronic apparatus according to claim 1, wherein
on the printed circuit board,
first wiring coupled to the first pad,
second wiring coupled to the second pad,
third wiring coupled to the third pad, and
fourth wiring coupled to the fourth pad are provided, and
the first wiring, the second wiring, the third wiring, and the fourth wiring pass between the fifth pad and the sixth pad.

3. The electronic apparatus according to claim 1, wherein
the third pad, the fourth pad, the fifth pad, and the sixth pad are oval, respectively.

4. The electronic apparatus according to claim 3, wherein
the first pad and the second pad are circular, respectively, and
the oval has
a diameter in the first direction larger than a diameter of the circle, and
a diameter in the second direction smaller than the diameter of the circle.

5. The electronic apparatus according to claim 2, wherein
between the fifth pad and the sixth pad,
a width of the first wiring, a width of the second wiring, a width of the third wiring, and a width of the fourth wiring are smaller than spacing between the third wiring and the first wiring, spacing between the first wiring and the fourth wiring, and spacing between the fourth wiring and the second wiring.

6. The electronic apparatus according to claim 2, wherein
the first wiring and the third wiring pass between the fourth pad and the fifth pad.

7. The electronic apparatus according to claim 2, wherein
a shortest distance between the fifth pad and the third wiring, a shortest distance between the third pad and the first wiring, a shortest distance between the fourth pad and the first wiring, a shortest distance between the fourth pad and the second wiring, and a shortest distance between the sixth pad and the second wiring are larger than a shortest distance between the third wiring and the first wiring, a shortest distance between the first wiring and the fourth wiring, and a shortest distance between the fourth wiring and the second wiring.
